(19) United States
(12) Patent Application Publication
(10) Pub. No.: US 2024/0022214 A1
(43) Pub. Date: Jan. 18, 2024

(54) OUT-OF-BAND BLOCKER REMOVING CALIBRATION-FREE WIDE-BAND LOW-NOISE AMPLIFIER STRUCTURE AND METHOD

(71) Applicant: Samsung Electronics Co., Ltd., Suwon-si, Gyeonggi-do (KR)

(72) Inventors: Junghwan HAN, Daejeon (KR); Pillseong KANG, Daejeon (KR); Juhui JEONG, Daejeon (KR)

(73) Assignees: Samsung Electronics Co., Ltd., Suwon-si (KR); The Industry & Academic Cooperation In Chungnam National University (IAC), Daejeon (KR)

(21) Appl. No.: 18/337,889

(22) Filed: Jun. 20, 2023

(30) Foreign Application Priority Data
Jul. 12, 2022 (KR) 10-2022-0085691

(51) Int. Cl. H03F 1/26; H03F 1/32; H03F 3/193

(52) U.S. Cl. CPC H03F 1/26; H03F 1/3205; H03F 3/193; H03F 2200/294; H03F 2200/171; H03F 2200/451

(57) ABSTRACT

A wide-band low-noise amplifier structure for removing an out-of-band blocker includes a transconductance pre-amplifier stage configured to convert a voltage signal into a current signal, a filter stage including a main path and an auxiliary path connected in parallel, the main path passing a first signal including all of the current signal, and the auxiliary path passing a second signal including only an out-of-band portion of the current signal, and a combination stage configured to output a third signal corresponding to a difference between the first signal and the second signal, the third signal including only an in-band portion of the current signal.

### CROSS-REFERENCE TO RELATED APPLICATION

This application is based on and claims priority under 35 U.S.C. § 119 to Korean Patent Application No. 10-2022-0085691, filed on Jul. 12, 2022, in the Korean Intellectual Property Office, the disclosure of which is incorporated by reference herein in its entirety.

### BACKGROUND

The inventive concepts relate to a wide-band low-noise amplifier structure, and particularly, to a calibration-free wide-band low-noise amplifier structure capable of removing an out-of-band blocker applied to a receiver in various wireless communication systems.

In wireless mobile communication, for example, 3G or 4G, using a frequency division duplexing (FDD) method in which transmission and receiving are simultaneously (or contemporaneously) performed, due to the limited isolation properties of a duplexer in use, a transmitter TX signal leaks to a receiver RX. The leakage signal (e.g., a blocker signal) may not only increase the non-linear properties of the receiver RX, but also deteriorate noise performance. This may finally deteriorate the signal-to-noise ratio (SNR) and sensitivity performance of the entire receiver RX.

To reduce receiver performance deterioration due to an out-of-band blocker, the blocker is removed through the application of a radio frequency (RF) filter, and the like, in a front-end of the receiver RX. This may be fundamentally improved by improving the isolation properties of a duplexer, or through the application of an additional band pass filter (BPF). However, the isolation properties of a currently available duplexer are about 52 dB and thus further improvement is restricted, and the use of an additional filter causes deterioration of noise properties and an increase in component costs due to an increase of insertion loss. Furthermore, as the number of frequency bands supported by a receiver RX has increased, in an existing duplexer a blocker (e.g., an interfering and/or leakage signal) is removable only in a fixed frequency area and an additional switch for selecting each band is included in the existing duplexer. This results in additional costs and an insertion loss increase. To remove the transmitter leakage signal from the receiver, in addition to the existing duplexer, various methods have been implemented.

FIG. 1 illustrates a system for removing a blocker through a feedforward path. Referring to FIG. 1, the system includes a main path that passes through an LNA and an auxiliary path that receive an in-band (IB) receiving signal fIB and an out-of-band blocker signal fBLK that are both amplified. The auxiliary path includes a mixer, a high-pass filter (HPF), a variable gain amplifier (VGA), and a phase shifter (PS) that passes only an out-of-band blocker, and then the blocker is removed through a combiner. The more accurately the amplitude and phase of a blocker component match between the main path and the auxiliary path, the more blockers are removed from an output end. However, to calibrate the phase and amplitude that differ according to the frequency, the system of FIG. 1 includes a phase shifter and a variable gain amplifier, and a blocker removal effect may be reduced due to a mismatch between the phase and the amplitude according to a temperature and an environment. Furthermore, due to different gain and phase properties for each frequency, there is a limit in removing a specific frequency blocker only.

FIG. 2 illustrates a system for removing a blocker by using a high-linearity manual mixer employing a mixer-first structure and a low-pass filter. Referring to FIG. 2, the system employs a method of removing a blocker by using a low-pass filter (LPF) having a high selectivity. Instead of an LNA, the system includes a high-linearity manual mixer that is strong (e.g., effective) against a blocker is arranged on the first path in a receiver, and a received signal is down-converted to a baseband (BB). Although the method may effectively remove a blocker, as an LNA is not applied to the first end, noise of the entire receiver may increase.

FIG. 3 illustrates a system for reducing a leakage signal by using an electrical balanced duplexer (EBD). Referring to FIG. 3, the system reduces a transmitter leakage signal in a receiver, by using an EBD employing a hybrid transformer instead of an existing duplexer. In an EBD operation, while a transmission signal is directly transmitted on an antenna port path in a transmitting port (TX port), for a case from the TX port to a receiving port (RX port), two signals with different phases may be simultaneously (or contemporaneously) induced due to the hybrid transformer. When the antenna port impedance and the balance network impedance are the same (or similar), two leakage signals transmitted to the receiver offset each other. Although the method may obtain a relatively high isolation (>60 dB), a rather complex balance network design is used, and blocker removing performance may be deteriorated due to a balance network impedance mismatch challenge. Furthermore, because it is difficult to the EBD to a wide-band frequency area, and removing only a transmission leakage signal of a specific frequency is possible, there is a limit in application of an overall out-of-band filter.

### SUMMARY

The inventive concepts provide a wide-band low-noise amplifier structure which removes a blocker while identically (or similarly) maintaining a gain and a phase in an out-of-band wide-band area, without using an additional phase shifter or a variable gain amplifier. According to embodiments, through implementation of a circuit RF filter in a low-noise amplifier (LNA) first located on a receiving path, a structure is provided to improve linearity and noise performance by removing or reducing a transmitter leakage signal.

According to an aspect of the inventive concepts, there is provided a wide-band low-noise amplifier structure for removing an out-of-band blocker, which includes a transconductance pre-amplifier stage configured to convert a voltage signal into a current signal, a filter stage including a main path and an auxiliary path connected in parallel, the main path passing a first signal including all of the current signal, and the auxiliary path passing a second signal including only an out-of-band portion of the current signal, and a combination stage configured to output a third signal corresponding to a difference between the first signal and the second signal, the third signal including only an in-band portion of the current signal.

The main path may include N branches, each of the N branches corresponding to a different phase among N phases, each of the N branches including a first frequency down-conversion mixer and a first frequency up-conversion mixer connected in series.

The auxiliary path may include an N-phase N-path filter, the N-phase N-path filter including a second frequency down-conversion mixer, a high-pass filter, and a second frequency up-conversion mixer connected in series.

Each of the first frequency down-conversion mixer, the first frequency up-conversion mixer, the second frequency down-conversion mixer and the second frequency up-conversion mixer may operate at an in-band frequency, the in-band frequency being a frequency of the in-band portion of the current signal.

The first signal and the second signal may have a same amplitude and phase, the auxiliary path may pass the second signal without additional gain and phase conversion, and the third signal may represent the first signal with an out-of-band blocker removed.

The auxiliary path may be configured to adjust a frequency of an in-band receiving signal to be filtered.

The high-pass filter may be configured to filter the in-band portion of the current signal.

Each of the first frequency down-conversion mixer, the first frequency up-conversion mixer, the second frequency down-conversion mixer and the second frequency up-conversion mixer may include a respective switch that switches on or off according to a local oscillator signal of the in-band frequency.

The auxiliary path may be configured to adjust a frequency of an in-band receiving signal by changing a frequency of the local oscillator signal.

The wide-band low-noise amplifier structure may further include a demodulator configured to demodulate the third signal, or a decoder configured to decode the third signal.

According to an aspect of the inventive concepts, there is provided a wide-band low-noise amplification method for removing an out-of-band blocker, which includes a transconductance pre-amplification operation of converting a voltage signal into a current signal, a main path filter operation of passing a first signal including all of the current signal, an auxiliary path filter operation of passing a second signal including only an out-of-band portion of the current signal, and a combination operation of outputting a third signal corresponding to a difference between the first signal and the second signal, the third signal including only an in-band portion of the current signal.

The passing the first signal may include first down-converting the current signal, and first up-converting a result of the first down-converting to obtain the first signal.

The passing the second signal may include second down-converting the current signal, filtering an output of the second down-converting, and second up-converting an output of the filtering to obtain the second signal.

The first down-converting, the first up-converting, the second down-converting and the second up-converting may be performed at an in-band frequency, the in-band frequency being a frequency of the in-band portion of the current signal.

The first signal and the second signal may have a same amplitude and phase, the passing the second signal may pass the second signal without additional gain or phase conversion, and the third signal may represent the first signal with an out-of-band blocker removed.

The passing the second signal may include adjusting a frequency of an in-band receiving signal to be filtered.

The filtering may filter the in-band portion of the output of the second down-converting.

Each of the first down-converting, the first up-converting, the second down-converting and the second up-converting may include switching a respective switch on or off according to a local oscillator signal of the in-band frequency.

The passing the second signal may include adjusting a frequency of an in-band receiving signal by changing a frequency of the local oscillator signal.

The wide-band low-noise amplification method may include demodulating the third signal, or decoding the third signal.

### BRIEF DESCRIPTION OF THE DRAWINGS

Embodiments of the inventive concepts will be more clearly understood from the following detailed description taken in conjunction with the accompanying drawings in which:

FIG. 1 illustrates a system for removing a blocker through a feedforward path;

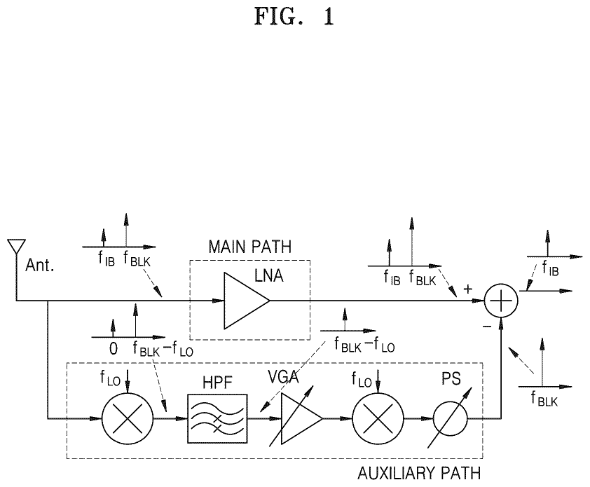

FIG. 2 illustrates a system for removing a blocker by using a high-linearity manual mixer employing a mixer-first structure and a low-pass filter;

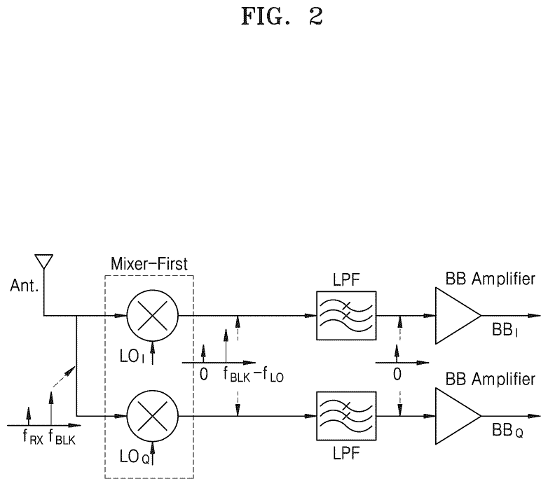

FIG. 3 illustrates a system for reducing a leakage signal by using an electrical balanced duplexer (EBD);

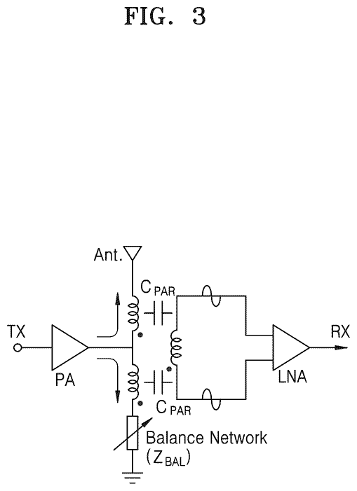

FIG. 4 is a block diagram of a configuration of a wide-band low-noise amplifier according to embodiments;

FIG. 5 is a circuit diagram of the wide-band low-noise amplifier of FIG. 4;

FIG. 6A is a circuit diagram of an auxiliary path employing an N-phase N-path filter;

FIG. 6B is an RLC equivalent circuit of the auxiliary path of FIG. 6A;

FIG. 7 is a waveform diagram of an N-phase signal applied to a frequency conversion mixer, according to embodiments;

FIG. 8 is a circuit diagram of a wide-band low-noise amplifier employing a 4-phase N-path filter, according to embodiments; and

FIG. 9 is a graph showing a simulation result of a voltage gain of a wide-band low-noise amplifier according to embodiments.

### DETAILED DESCRIPTION

The inventive concepts will now be described more fully with reference to the accompanying drawings, in which embodiments of the inventive concepts are shown. The inventive concepts may, however, be embodied in many different forms and should not be construed as being limited to embodiments set forth herein. Like reference numerals in the drawings denote like elements performing substantially the same function.

The purpose and effects of the inventive concepts may be understood or clarified smoothly by the following description, but not limited by the following description only. Furthermore, in the following description, when detailed descriptions about related well-known functions or structures are determined to make the gist of the disclosure unclear, the detailed descriptions will be omitted herein.

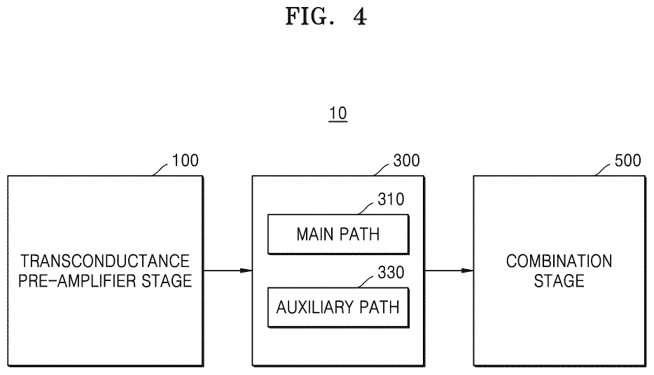

FIG. 4 is a block diagram of a configuration of a wide-band low-noise amplifier structure 10 according to embodiments. Referring to FIG. 4, the wide-band low-noise amplifier structure 10 may include a transconductance pre-amplifier stage 100, a filter stage 300, and/or a combination stage 500. The wide-band low-noise amplifier structure 10 may cancel an out-of-band signal (e.g., an out-of-band blocker corresponding to a duplex leakage signal) and output only an in-band receiving signal.

The wide-band low-noise amplifier structure 10 may reduce performance deterioration, without separate gain and phase calibration, and effectively remove not only an out-of-band specific frequency blocker, such as a transmitter leakage signal, but also a blocker from an out-of-band wide-band frequency area. The wide-band low-noise amplifier structure 10 may improve linearity and noise properties of the entire receiver.

The wide-band low-noise amplifier structure 10 may effectively remove an out-of-band blocker using the filter stage 300 in which a main path 310, where an out-of-band gain and a phase are the same (or similar), and an auxiliary path 330 including an N-path filter are combined with each other. The wide-band low-noise amplifier structure 10 may be distinguished from existing technology in that a gain and a phase are identically (or similarly) maintained in the out-of-band wide-band area, without using an additional phase shifter or a variable gain amplifier for gain and phase calibration according to the frequency. The wide-band low-noise amplifier structure 10 may be used in receiving stages (e.g., receivers) of various wireless communication systems, such as a frequency division duplexing (FDD) cellular communication system (e.g., 3G, LTE, 5G, and Internet-of-things (IoT)), a wide-band communication system, and the like. According to embodiments, the wide-band low-noise amplifier structure 10 may be included in a receiver (or transceiver) of a user equipment. The user equipment may be fixed or mobile and may refer to any device that may communicate with a base station to transmit and receive data and/or control information. For example, the user equipment may be referred to as a terminal, a terminal equipment, a mobile station (MS), a mobile terminal (MT), a user terminal (UT), a subscriber station (SS), a wireless device, a handheld device, or the like. According to embodiments, the wide-band low-noise amplifier structure 10 may be included in a receiver (or transceiver) of a base station. The base station may generally refer to a fixed station that communicates with user equipment and/or other base stations, and may exchange data and control information by communicating with user equipment and/or other base stations. For example, the base station may also be referred to as a Node B, an evolved-Node B (eNB), a next generation Node B (gNB), a sector, a site, a base transceiver system (BTS), an access point (AP), a relay node, a remote radio head (RRH), a radio unit (RU), a small cell, or the like.

The wide-band low-noise amplifier structure 10 may provide performance improvement by effectively removing a transmitter (TX) leakage signal particularly from wireless communication implementing FDD communication, such as 3G or 4G mobile communication, and the like. In a cellular FDD system, various calibration methods are employed for secondary non-linearity improvement due to the transmission leakage signal that has not been removed in spite of the use of a front-end duplexer, and thus, a cost increase occurs due to an increase in test time. The wide-band low-noise amplifier structure 10 according to the inventive concepts may obtain an effect of additional cost reduction through the linearity and noise properties improvement in the entire receiving stage and the removal of a complex linearity calibration process, without using an additional front-end RF filter in various bands and frequency areas.

It is confirmed that, in a simulation result of embodiments designed through a complementary metal-oxide semiconductor (CMOS) process, the wide-band low-noise amplifier structure 10 has an effect of removing a transmitting leakage frequency blocker of 20 dB or more and a blocker of 30 dB or more in a wide-band out-of-band frequency area.

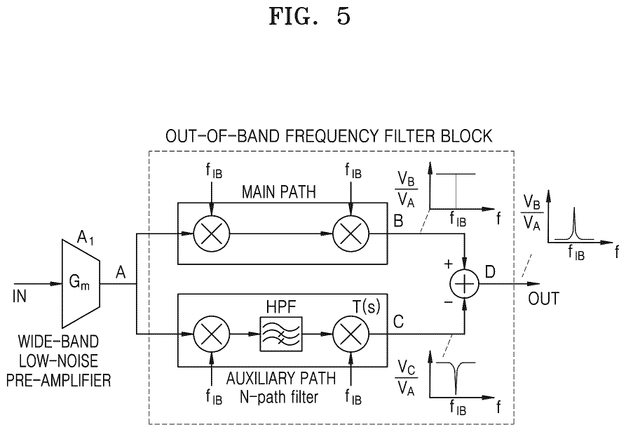

FIG. 5 is a block diagram of the wide-band low-noise amplifier structure 10 of FIG. 4. Referring to FIG. 5, the wide-band low-noise amplifier structure 10 may remove an out-of-band blocker from a wide-band area by using an N-path filter having band-tunable band-reject filter (BRF) properties. The wide-band low-noise amplifier structure 10 may be used as a method suitable for next-generation communication according to a multi-mode multi-band (MMMB) transceiver design for supporting various frequency bands and various communication specifications with one transceiver, which may be implemented according to the recent development of wireless communication.

The transconductance pre-amplifier stage 100 may convert a voltage signal applied to an input terminal IN thereof into a current signal and transmit the current signal as an input of the filter stage 300. According to embodiments, the voltage signal may correspond to a received FDD signal including a TX leakage signal. The transconductance pre-amplifier stage 100 may convert the voltage signal applied to the input terminal IN thereof into a current signal, due to the wide-band matching and gain properties, and transmit the current signal as inputs of the main path 310 and the auxiliary path 330 of the filter stage 300. The transconductance pre-amplifier stage 100 may include a transconductance pre-amplifier (e.g., a transconductance amplifier) to maintain wide-band matching and low noise, and high linearity maintenance.

The filter stage 300 may include the main path 310 and the auxiliary path 330. The filter stage 300 is configured to substantially filter an out-of-band frequency.

The main path 310 may pass all frequency signals (e.g., a first signal) in and out of band (e.g., all signals regardless of frequency including in-band signals and out-of-band signals). The main path 310 may include N-phases (e.g., N branches each corresponding to a different phase among N phases), and each phase (e.g., branch) may be configured such that a frequency down-conversion mixer and a frequency up-conversion mixer are connected in series. In the following description, the frequency down-conversion mixer and the frequency up-conversion mixer may be collectively called a frequency conversion mixer.

The auxiliary path 330 may pass all out-of-band signals (e.g., a second signal including only an out-of-band portion of the current signal) while canceling only an in-band receiving signal. The auxiliary path 330 may be connected in parallel with the main path 310, and may include an N-phase N-path filter, in which the N-path filter may be configured such that a frequency down-conversion mixer, a high-pass filter, and a frequency up-conversion mixer are connected in series.

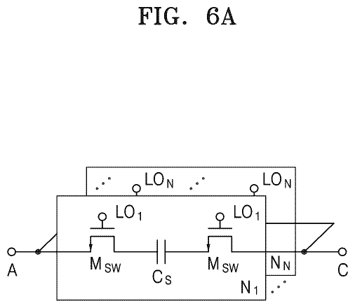

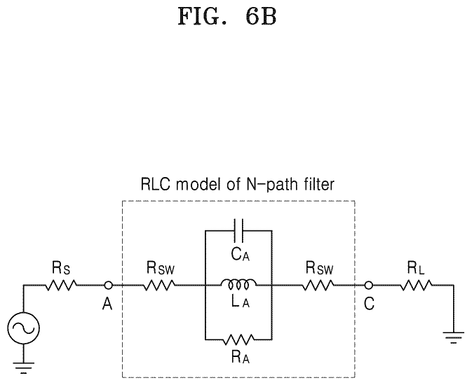

FIG. 6A is a circuit diagram of the auxiliary path 330 employing an N-phase N-path filter, and FIG. 6B is an RLC equivalent circuit of the auxiliary path 330 of FIG. 6A.

Referring to FIG. 6A, the auxiliary path 330 may include an N-phase N-path filter, and the N-path filter may be configured such that a frequency down-conversion mixer, an HPF, and a frequency up-conversion mixer are connected in series. The auxiliary path 330 may exhibit band cancellation properties overall. The frequency conversion mixer may include a switch M_{SW} performing an on/off operation in response to a signal of a local oscillator (LO). According to embodiments, such a switch M_{SW} may be used in combination with the LO to implement both the frequency down-conversion mixer and the frequency up-conversion mixer. The N-path filter may include the switch M_{SW} performing an on/off operation in response to a signal of the local oscillator LO having N phases. According to embodiments, each of the N phases may correspond to a different branch of the auxiliary path, each of the different branches including a respective frequency down-conversion mixer, HPF, and frequency up-conversion mixer connected in series. The HPF may include a serial capacitor C₅ having high-pass properties.

The total gain considering the transconductance pre-amplifier stage 100, the filter stage 300, and the combination stage 500 of the wide-band low-noise amplifier structure 10 may be expressed by Equation 1 below.

$${A}_{V} ( s ) = \frac{{V}_{OUT}}{{V}_{IN}} ≅ {A}_{1} ( 1 - T ( s ) ) \qquad [ Equation 1 ]$$

In Equation 1, “A1” denotes a transconductance gain of a wide-band pre-amplifier of the transconductance pre-amplifier stage 100, and “T(s)” denotes an N-Path filter transfer function of the auxiliary path 330.

Referring to FIG. 6B, the N-phase N-path filter may be expressed by a parallel RLC equivalent circuit, and each component value may be determined as shown in Equation 2 below.

$${R}_{A} = \frac{{N}^{2} {sin}^{2} ( π / N )}{{π}^{2} - {N}^{2} {sin}^{2} ( π / N )} ( {R}_{S} + {R}_{L} ) \qquad [ Equation 2 ]$$

$${C}_{A} = \frac{{π}^{2}}{2 N {sin}^{2} ( π / N )} C$$

$${L}_{A} = \frac{1}{{( 2 π {f}_{LO} )}^{2} {C}_{A}}$$

In Equation 2, N denotes a degree of the N-path filter and shows a case in which the local oscillator LO having N phases is applied to each switch. “R_{S}” denotes a source impedance of the N-path filter, and “RL” denotes an input impedance of the next stage.

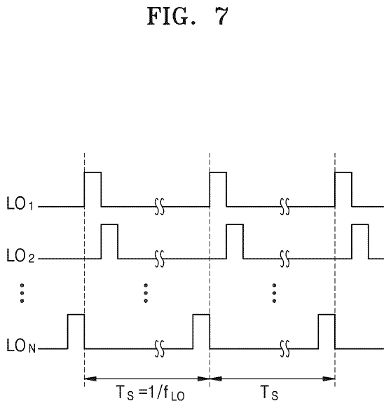

FIG. 7 is a waveform diagram of an N-phase signal applied to the frequency conversion mixer of FIG. 6. Referring to FIG. 7, the waveform of an N-phase LO signal in a cycle (T_{S}=1/ƒ_{LO}) generated by the local oscillator LO having N phases may be confirmed. “ƒ_{LO}” denotes the frequency of a signal of the local oscillator LO being applied. According to embodiments, the frequency ƒ_{LO} is the same as (or similar to) a band-reject frequency (e.g., the frequency of the in-band (IB) receiving signal) of the N-path filter (ƒ_{LO32} ƒ_{IB}). According to embodiments, the local oscillator LO is controlled to generate the N-phase signal(s) by a controller (included along with the wide-band low-noise amplifier structure in the user equipment, base station, etc.).

In the parallel RLC equivalent circuit, when ƒ_{LO}=ƒ_{IB}, LA and CA resonate, and thus, only a value R_{A} is seen from the frequency. Assuming that R_{SW}=0 and N=4 (4-phase N-path filter) for simplification of the equation, in an in-band frequency ƒ_{IB}, the transfer function of the N-path filter and a gain A_{V}(s) of the wide-band low-noise amplifier structure 10 may be expressed by Equation 3 and Equation 4 below.

$${T ( s ) \vert}_{f = {f}_{IB}} = \frac{{V}_{C}}{{V}_{A}} ≅ \frac{{R}_{L}}{{R}_{A} + {R}_{L}} {V}_{IN} ≅ \frac{{R}_{L}}{4.28 ( {R}_{S} + {R}_{L} ) + {R}_{L}} {V}_{IN} ≅ \frac{{R}_{L}}{4.28 {R}_{S} + 5.28 {R}_{L}} {V}_{IN} \qquad [ Equation 3 ]$$

$${A}_{V} ( s ) = \frac{{V}_{OUT}}{{V}_{IN}} + {A}_{1} ( 1 - \frac{{R}_{L}}{4.28 {R}_{S} + 5.28 {R}_{L}} ) \qquad [ Equation 4 ]$$

In Equation 4, assuming that RIN>>RS, the total gain of the wide-band low-noise amplifier structure 10 may be simplified such that A_{V}=0.81A₃. In contrast, in an out-of-band (OB) frequency area ƒ_{OB}, not the ƒ_{IB} frequency area, the RLC equivalent circuit has a capacitive or inductive value. In other words, when the blocker frequency ƒ_{OB} is sufficiently separated compared with the frequency ƒ_{IB}, in the ƒ_{OB} frequency area, LA or CA may be seen as a short (V_{A}=V_{C}). Accordingly, the total gain of the wide-band low-noise amplifier structure 10 may be expressed by Equation 5 below.

$${A}_{V} ( s ) = \frac{{V}_{OUT}}{{V}_{IN}} = {A}_{1} ( 1 - T ( S ) ) ≅ 0 \qquad [ Equation 5 ]$$

As may be seen from Equation 4 and Equation 5, the wide-band low-noise amplifier structure 10 may have a slight gain decrease, but may effectively remove all out-of-band frequency blockers without separate gain and phase calibration. It may be seen that it is distinguished from an existing method of removing only one out-of-band frequency component in that all out-of-band frequency blockers are removable from a wide-band area.

The auxiliary path 330 may be configured to adjust the frequency of an in-band receiving signal to be canceled (e.g., filtered). The auxiliary path 330, compared with an existing duplex capable of removing only a blocker with respect to a fixed frequency component, may enable an adjustment of a blocker-removing frequency area through a frequency change of the N-path filter. This means that removing a blocker in a wide-band area is possible in contrast with the existing blocker removing structure. The auxiliary path 330 may enable the frequency adjustment for canceling an in-band receiving signal through a change in the local oscillator LO signal frequency of the N-path filter. This enables adjustment and selection of a frequency in which a blocker to be removed exists. According to embodiments, the frequency of the local oscillator LO is changed to adjust the blocker-removing frequency area by the controller (included along with the wide-band low-noise amplifier structure in the user equipment, base station, etc.).

The frequency down-conversion mixer and the frequency up-conversion mixer, of both the main path 310 and the auxiliary path 330, may identically (or similarly) operate at the in-band frequency ƒ_{IB} (e.g., the switches M_{SW} of these mixers may perform on/off operations in response to LO signals of the in-band frequency ƒ_{IB}). In other words, by identically (or similarly) applying the frequency conversion mixer operating at the in-band frequency ƒ_{IB}, except the HPF, to the main path 310 and the auxiliary path 330, the amplitude and phase of an out-of-band signal according to the frequency may be maintained the same (or similar). Accordingly, the filter stage 300 may remove an out-of-band blocker without calibrating the amplitude and phase of a signal. This means that variable gain amplifiers and phase shifters for calibrating gain and phase are unnecessary, unlike the existing method of removing an out-of-band blocker.

The main path 310 and the auxiliary path 330 are configured to have the same amplitude and phase (or similar amplitudes and phases), and thus, the auxiliary path 330 is capable of transmitting a signal with the same gain and phase (or similar gains and phases) compared to the main path 310 in an out-of-band, without additional gain and phase conversion, thereby removing an out-of-band blocker in the combination stage 500.

The combination stage 500 is connected to a rear end of the filter stage 300 and may output a signal equivalent to a difference between an output of the main path 310 and an output of the auxiliary path 330 (e.g., a third signal corresponding to a difference between the first signal and the second signal). The combination stage 500 may combine the output signals of the main path 310 and the auxiliary path 330 and finally produce a difference signal to thus cancel an out-of-band signal and output only an in-band receiving signal from an output terminal OUT. According to embodiments, the difference signal may be output to a demodulator, a decoder and/or at least one processor (e.g., included with the wide-band low-noise amplifier structure in the user equipment, the base station, etc.) and thereby be demodulated, decoded and/or further processed (e.g., in accordance with a corresponding application).

In the following description, a simulation result of the inventive concepts is described.

In embodiments of the inventive concepts, it is intended that the wide-band low-noise amplifier structure 10 employing the N-path filter is designed using a 65 nm CMOS process, and the performance thereof is proved through a simulation. In the simulation, what are assumed are Band 8 (RX frequency fRX=940 MHz and TX frequency fTX=895 MHz), Band 2 (fRX=1960 MHz and fTX=1880 MHz), and Band 7 (fRX=2660 MHz and fTX=2540 MHz) of long-term evolution (LTE) that is a frequency division method in cellular wireless communication.

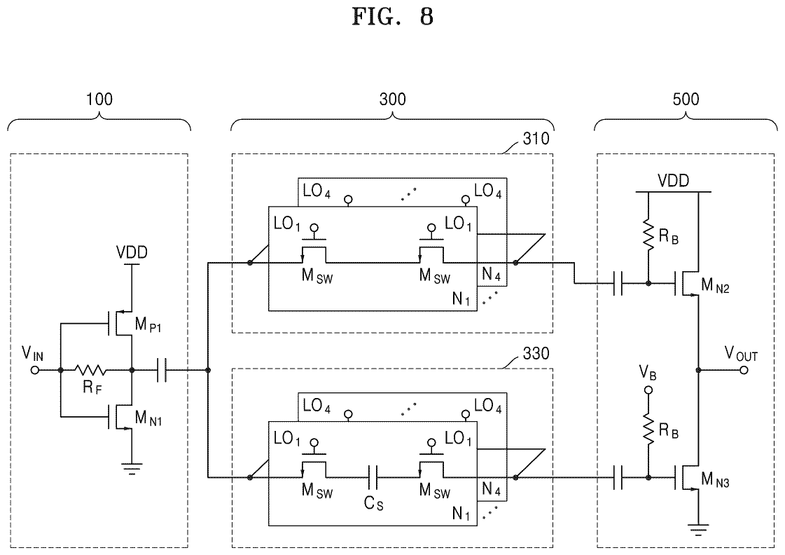

FIG. 8 is a circuit diagram of the wide-band low-noise amplifier structure 10 employing a 4-phase N-path filter, according to embodiments. Referring to FIG. 8, illustrated is an example of a circuit diagram of the out-of-band blocker removing the wide-band low-noise amplifier structure 10. The circuit diagram may include a wide-band transconductance pre-amplifier (or amplifier) of an inverter type using resistance feedback R_{F}, a 4-phase down/up mixer of a main path, a 4-phase N-path filter of an auxiliary path, and a common-source+source follower combiner. The 4-phase N-path filter may include, as described above, four pairs of the switches M_{SW} and the serial capacitor C_{S} (e.g., 4 serial capacitors C_{S}). In this state, to implement the same gain and phase change (or similar gains and phase changes) in the main path 310 and the auxiliary path 330, the switch M_{SW} of the same amplitude (or similar amplitudes) is used in the frequency down/up mixer.

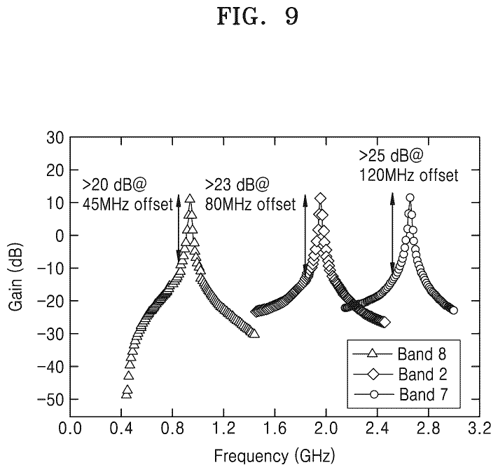

FIG. 9 is a graph showing a simulation result of a voltage gain of the wide-band low-noise amplifier structure 10 according to embodiments. Referring to FIG. 9, a voltage gain simulation result of the wide-band low-noise amplifier structure 10 for removing an out-of-band blocker according to the frequency is illustrated with respect to the LTE Band 8, Band 2, and Band 7. The out-of-band blocker removing properties of 20 dB, 23 dB, 25 dB, or more respectively in Band 8, Band 2, and Band 7 based on in a transmission leakage signal frequency ƒ_{TX} are illustrated. Furthermore, it may be seen that an out-of-band blocker removal effect of all 30 dB or more is stably secured in a 300 MHz frequency offset ƒ_{offset}. In the wide-band low-noise amplifier structure 10 for removing an out-of-band blocker according to embodiments, as may be seen from the simulation result, without additional gain and phase calibration for each frequency, stable blocker removing properties are shown in an out-of-band wide-band frequency area of various frequency bands, which is distinguished from other existing blocker removing methods.

The wide-band low-noise amplification method for removing an out-of-band blocker according to embodiments of the inventive concepts may include a pre-amplification operation, a main path filter operation, an auxiliary path filter operation, and/or a combination operation.

In the pre-amplification operation, a voltage signal applied to an input terminal thereof may be converted into a current signal. The pre-amplification operation may mean an operation performed in the transconductance pre-amplifier stage described above.

In the main path filter operation, the signal having been converted in the pre-amplification operation is received, and all frequency signals in and out of band (e.g., a first signal including all of the current signal) may be passed. The main path filter operation may mean an operation performed in the main path described above.

In the auxiliary path filter operation, the signal having been converted in the pre-amplification operation is received, and only an in-band receiving signal is removed and all out-of-band signals (e.g., a second signal including only an out-of-band portion of the current signal) may be passed. The auxiliary path filter operation may mean an operation performed in the auxiliary path described above.

In the combination operation, a difference between the output signals from the main path filter operation and the auxiliary path filter operation may be output (e.g., a third signal corresponding to aforementioned difference may be output). The combination operation may mean an operation performed in the combination stage described above.

According to embodiments, the passing of the first signal may include first down-converting the current signal, and first up-converting a result of the first down-converting to obtain the first signal, consistent with the discussion of the main path above.

According to embodiments, the passing of the second signal may include second down-converting the current signal, filtering an output of the second down-converting, and second up-converting an output of the filtering to obtain the second signal, consistent with the discussion of the auxiliary path above. According to embodiments, the filtering may filter the in-band portion of the output of the second down-converting.

According to embodiments, the first down-converting, the first up-converting, the second down-converting and the second up-converting may be performed at an in-band frequency, the in-band frequency being a frequency of the in-band portion of the current signal. According to embodiments, each of the first down-converting, the first up-converting, the second down-converting and the second up-converting may include switching a respective switch on or off according to a local oscillator signal of the in-band frequency.

According to embodiments, the first signal and the second signal may have a same amplitude and phase (or similar amplitudes and/or phases), the passing of the second signal may pass the second signal without additional gain or phase conversion, and the third signal may represent the first signal with an out-of-band blocker removed.

According to embodiments, the passing of the second signal may include adjusting a frequency of an in-band receiving signal to be filtered.

According to embodiments, the passing of the second signal may include adjusting a frequency of an in-band receiving signal by changing a frequency of the local oscillator signal.

According to embodiments, the wide-band low-noise amplification method may include demodulating the third signal, or decoding the third signal.

Conventional devices and methods for filtering an out-of-band blocker signal rely on a phase shifter and a variable gain amplifier to match the phase and amplitude of blocker components between main and auxiliary paths. However, the phase and amplitude generated by such phase shifters and variable gain amplifiers, respectively, vary according to temperature and environmental conditions. Accordingly, the conventional devices and methods are unable to filter the out-of-band blocker signal with sufficient reliability. Also, the conventional devices and methods are unable to filter blocker signals of both specific frequencies and wide-band frequencies, instead specializing in filtering one of either specific frequencies or wide-band frequencies. Accordingly, the conventional devices and methods are unable to filter the out-of-band blocker signal with sufficient reliability in dynamic blocker signal scenarios.

However, according to embodiments, improved devices and methods are provided for filtering an out-of-band blocker signal. For example, the improved devices and methods operate both of main and auxiliary paths at an in-band frequency. As a result, an amplitude and phase of an out-of-band signal remains the same (or similar) between the main and auxiliary paths. Accordingly, the improved devices and methods are able to filter the out-of-band blocker without the use of the phase shifters and variable gain amplifiers of the conventional devices and methods (and the temperature and environmental variability associated therewith). Also, the improved devices and methods are capable of removing out-of-band blockers over a wide-band area and/or adjusting a blocker-removing frequency area, for example, through a frequency change of an N-path filter. Therefore, the improved devices and methods overcome the deficiencies of the conventional devices and methods to at least filter an out-of-band blocker signal with greater reliability, including in dynamic blocker signal scenarios.

According to embodiments, operations described herein as being performed by the user equipment, the base station, the controller, the demodulator, the decoder and/or the at least one processor may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

While the inventive concepts have been particularly shown and described with reference to embodiments thereof, it will be understood that various changes in form and details may be made therein without departing from the spirit and scope of the following claims.

What is claimed is:

1. A wide-band low-noise amplifier structure for removing an out-of-band blocker, the wide-band low-noise amplifier structure comprising:
a transconductance pre-amplifier stage configured to convert a voltage signal into a current signal;
a filter stage including a main path and an auxiliary path connected in parallel, the main path passing a first signal including all of the current signal, and the auxiliary path passing a second signal including only an out-of-band portion of the current signal; and
a combination stage configured to output a third signal corresponding to a difference between the first signal and the second signal, the third signal including only an in-band portion of the current signal.

2. The wide-band low-noise amplifier structure of claim 1, wherein the main path includes N branches, each of the N branches corresponding to a different phase among N phases, each of the N branches including a first frequency down-conversion mixer and a first frequency up-conversion mixer connected in series.

3. The wide-band low-noise amplifier structure of claim 2, wherein the auxiliary path includes an N-phase N-path filter, the N-phase N-path filter including a second frequency down-conversion mixer, a high-pass filter, and a second frequency up-conversion mixer connected in series.

4. The wide-band low-noise amplifier structure of claim 3, wherein each of the first frequency down-conversion mixer, the first frequency up-conversion mixer, the second frequency down-conversion mixer and the second frequency up-conversion mixer operates at an in-band frequency, the in-band frequency being a frequency of the in-band portion of the current signal.

5. The wide-band low-noise amplifier structure of claim 4, wherein
the first signal and the second signal have a same amplitude and phase;
the auxiliary path passes the second signal without additional gain and phase conversion; and
the third signal represents the first signal with an out-of-band blocker removed.

6. The wide-band low-noise amplifier structure of claim 1, wherein the auxiliary path is configured to adjust a frequency of an in-band receiving signal to be filtered.

7. A wide-band low-noise amplification method for removing an out-of-band blocker, the method comprising:
a transconductance pre-amplification operation of converting a voltage signal into a current signal;
a main path filter operation of passing a first signal including all of the current signal;
an auxiliary path filter operation of passing a second signal including only an out-of-band portion of the current signal; and
a combination operation of outputting a third signal corresponding to a difference between the first signal and the second signal, the third signal including only an in-band portion of the current signal.

8. The wide-band low-noise amplification method of claim 7, wherein the passing the first signal comprises:
first down-converting the current signal; and
first up-converting a result of the first down-converting to obtain the first signal.

9. The wide-band low-noise amplification method of claim 8, wherein the passing the second signal comprises:
second down-converting the current signal;
filtering an output of the second down-converting; and
second up-converting an output of the filtering to obtain the second signal.

10. The wide-band low-noise amplification method of claim 9, wherein the first down-converting, the first up-converting, the second down-converting and the second up-converting are performed at an in-band frequency, the in-band frequency being a frequency of the in-band portion of the current signal.

11. The wide-band low-noise amplification method of claim 10, wherein
the first signal and the second signal have a same amplitude and phase;
the passing the second signal passes the second signal without additional gain or phase conversion; and
the third signal represents the first signal with an out-of-band blocker removed.

12. The wide-band low-noise amplification method of claim 7, wherein the passing the second signal comprises adjusting a frequency of an in-band receiving signal to be filtered.

13. The wide-band low-noise amplifier structure of claim 3, wherein the high-pass filter is configured to filter the in-band portion of the current signal.

14. The wide-band low-noise amplifier structure of claim 4, wherein each of the first frequency down-conversion mixer, the first frequency up-conversion mixer, the second frequency down-conversion mixer and the second frequency up-conversion mixer includes a respective switch that switches on or off according to a local oscillator signal of the in-band frequency.

15. The wide-band low-noise amplifier structure of claim 14, wherein
the auxiliary path is configured to adjust a frequency of an in-band receiving signal by changing a frequency of the local oscillator signal.

16. The wide-band low-noise amplifier structure of claim 1, further comprising:
a demodulator configured to demodulate the third signal; or
a decoder configured to decode the third signal.

17. The wide-band low-noise amplification method of claim 9, wherein the filtering filters the in-band portion of the output of the second down-converting.

18. The wide-band low-noise amplification method of claim 10, wherein each of the first down-converting, the first up-converting, the second down-converting and the second up-converting includes switching a respective switch on or off according to a local oscillator signal of the in-band frequency.

19. The wide-band low-noise amplification method of claim 18, wherein
the passing the second signal comprises adjusting a frequency of an in-band receiving signal by changing a frequency of the local oscillator signal.

20. The wide-band low-noise amplification method of claim 7, further comprising:
demodulating the third signal; or
decoding the third signal.
